(19) United States
(12) Patent Application Publication
(10) Pub. No.: US 2026/0175989 A1
(43) Pub. Date: Jun. 25, 2026

(54) ELECTRICAL POWER SUPPLY SYSTEM, MOVING OBJECT, CONTROL METHOD, AND STORAGE MEDIUM

(71) Applicant: HONDA MOTOR CO., LTD., Tokyo (JP)

(72) Inventor: Kenta Shuto, Wako-shi (JP)

(21) Appl. No.: 19/428,703

(22) Filed: Dec. 22, 2025

(30) Foreign Application Priority Data
Dec. 24, 2024 (JP) 2024-226848

(51) Int. Cl. B64D 31/18; G01R 31/367; G01R 31/382; G01R 31/396; H02J 1/108

(52) U.S. Cl. CPC B64D 31/18; G01R 31/367; G01R 31/382; G01R 31/396; H02J 1/108

(57) ABSTRACT

An electrical power supply system includes: an estimation unit capable of estimating a first residual capacity, which is a residual capacity of a first electrical power storage device, based on an amount of electrical power charged and discharged by the first electrical power storage device; and an update control unit which, in a state in which, by controlling a first connection device, a second electrical power storage device is connected via a first connection circuit and a second electrical power supply circuit to a first electrical power supply circuit, is capable of disconnecting the first electrical power storage device from the first electrical power supply circuit by controlling a first disconnection device, and is capable of updating a first residual capacity estimated value, which is the first residual capacity estimated by the estimation unit, based on an open circuit voltage of the first electrical power storage device.

### CROSS-REFERENCE TO RELATED APPLICATIONS

This application is based upon and claims the benefit of priority from Japanese Patent Application No. 2024-226848 filed on Dec. 24, 2024, the contents of which are incorporated herein by reference.

### BACKGROUND OF THE INVENTION

### Field of the Invention

The present disclosure relates to an electrical power supply system, a moving object, a control method, and a storage medium.

### Description of the Related Art

In JP 2004-245673 A, there is disclosed a technique for acquiring a residual capacity of an electrical power storage body such as a lithium ion secondary battery that is mounted on a hybrid vehicle or the like.

### SUMMARY OF THE INVENTION

There is a long awaited need for a technology that is capable of suitably estimating the residual capacity of an electrical power storage device.

The present disclosure has the object of solving the aforementioned problem.

A first aspect of the present disclosure is characterized by an electrical power supply system, comprising: a first electrical power supply circuit configured to be connected to a first load device; a second electrical power supply circuit configured to be connected to a second load device; a first electrical power storage device configured to be connected via a first disconnection device to the first electrical power supply circuit; a second electrical power storage device configured to be connected via a second disconnection device to the second electrical power supply circuit; a first connection circuit including a first connection device configured to connect the first electrical power supply circuit and the second electrical power supply circuit; an estimation unit configured to estimate a first residual capacity, which is a residual capacity of the first electrical power storage device, based on an amount of electrical power that is charged and discharged by the first electrical power storage device; and an update control unit configured to, in a state in which, by controlling the first connection device, the second electrical power storage device is connected via the first connection circuit and the second electrical power supply circuit to the first electrical power supply circuit, disconnect the first electrical power storage device from the first electrical power supply circuit by controlling the first disconnection device, and update a first residual capacity estimated value, which is the first residual capacity estimated by the estimation unit, based on an open circuit voltage of the first electrical power storage device.

A second aspect of the present disclosure is characterized by a moving object comprising the electrical power supply system according to the first aspect.

A third aspect of the present disclosure is characterized by a control method for controlling an electrical power supply system including a first electrical power supply circuit configured to be connected to a first load device, a second electrical power supply circuit configured to be connected to a second load device, a first electrical power storage device configured to be connected via a first disconnection device to the first electrical power supply circuit, a second electrical power storage device configured to be connected via a second disconnection device to the second electrical power supply circuit, and a first connection circuit including a first connection device configured to connect the first electrical power supply circuit and the second electrical power supply circuit, the control method comprising: a first residual capacity estimating step of estimating a first residual capacity, which is a residual capacity of the first electrical power storage device, based on an amount of electrical power that is charged and discharged by the first electrical power storage device; and a first residual capacity estimated value updating step of, in a state in which, by controlling the first connection device, the second electrical power storage device is connected via the first connection circuit and the second electrical power supply circuit to the first electrical power supply circuit, disconnecting the first electrical power storage device from the first electrical power supply circuit by controlling the first disconnection device, and updating a first residual capacity estimated value, which is the first residual capacity estimated in the first residual capacity estimating step, based on an open circuit voltage of the first electrical power storage device.

A fourth aspect of the present disclosure is characterized by a non-transitory storage medium storing a program for causing a computer to execute the control method according to the third aspect.

According to the present disclosure, the residual capacity of the electrical power storage device is capable of being suitably estimated.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a schematic diagram of a moving object;

FIG. 2 is a schematic diagram of an electrical power supply system according to one embodiment;

FIG. 3 is a schematic diagram illustrating an example of a first electrical power storage device according to the one embodiment;

FIG. 4 is a schematic diagram illustrating an example of a backflow prevention device according to the one embodiment;

FIG. 5 is a schematic diagram illustrating another example of the backflow prevention device according to the one embodiment;

FIG. 6 is a control block diagram of a control device according to the one embodiment;

FIG. 7 is a diagram showing operations of the electrical power supply system at a normal time according to the one embodiment;

FIG. 8 is a flowchart of a residual capacity acquisition process;

FIG. 9 is a flowchart of the residual capacity acquisition process;

FIG. 10 is a flowchart of a state determination process;

FIG. 11A is a diagram showing a relationship between a flight time of the moving object and an altitude of the moving object; and

FIG. 11B is a diagram showing a relationship between the flight time of the moving object and an error contained in a residual capacity estimated value of the electrical power storage device.

### DETAILED DESCRIPTION OF THE INVENTION

A residual capacity (SOC: state of charge) of an electrical power storage device can be calculated based on, for example, an actual measurement value of an open circuit voltage of the electrical power storage device. In a state in which an electrical power supply circuit is connected to the electrical power storage device, the residual capacity of the electrical power storage device can be estimated by adding or subtracting, to or from a known residual capacity, an amount of charge (a charging/discharging electrical power) that has flowed in or out of the electrical power storage device. The residual capacity that is estimated in this manner is referred to as a residual capacity estimated value. The amount of charge that has flowed in and out of the electrical power storage device is calculated, for example, based on a measurement value of a sensor (e.g., an electrical current sensor). In the case that an error is contained in the measurement value of the sensor, the error is accumulated in the residual capacity estimated value. Therefore, it is preferable to eliminate any error that is contained in the residual capacity estimated value, by measuring again the open circuit voltage of the electrical power storage device at a stage after a certain amount of time has elapsed.

However, when the electrical power storage device is simply disconnected from the electrical power supply circuit in order to measure again the open circuit voltage of the electrical power storage device, there is a concern in that the electrical power may no longer be supplied to the load device.

According to the present disclosure, while reliably maintaining the supply of the electrical power to the load device, it is possible to eliminate any error contained in the residual capacity estimated value of the electrical power storage device.

### Moving Object 10

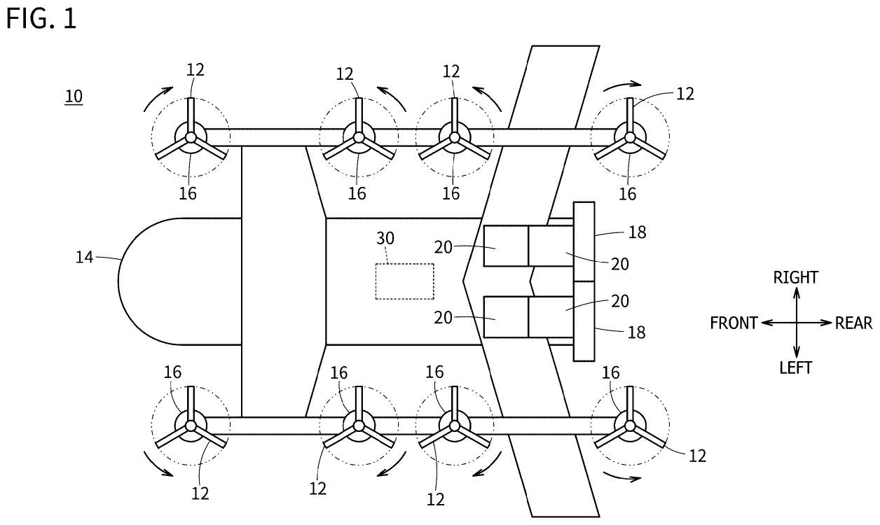

FIG. 1 is a schematic diagram of a moving object 10. The moving object 10 of one embodiment is an electric vertical take-off and landing aircraft (eVTOL aircraft). The moving object 10 is equipped with eight VTOL rotors 12. The VTOL rotors 12 generate upward thrust for a fuselage 14. The moving object 10 is equipped with eight electric motors 16. One of the electric motors 16 drives one of the VTOL rotors 12. The moving object 10 includes two cruise rotors 18. The cruise rotors 18 generate forward thrust for the fuselage 14. The moving object 10 is equipped with four electric motors 20. Two of the electric motors 20 drive one of the cruise rotors 18. The moving object 10 is equipped with an electrical power supply system 30, which will be described later. The moving object 10 is not limited to being an aircraft, but may be a ship, an automobile, a train, or the like.

### Configuration of Electrical Power Supply System 30

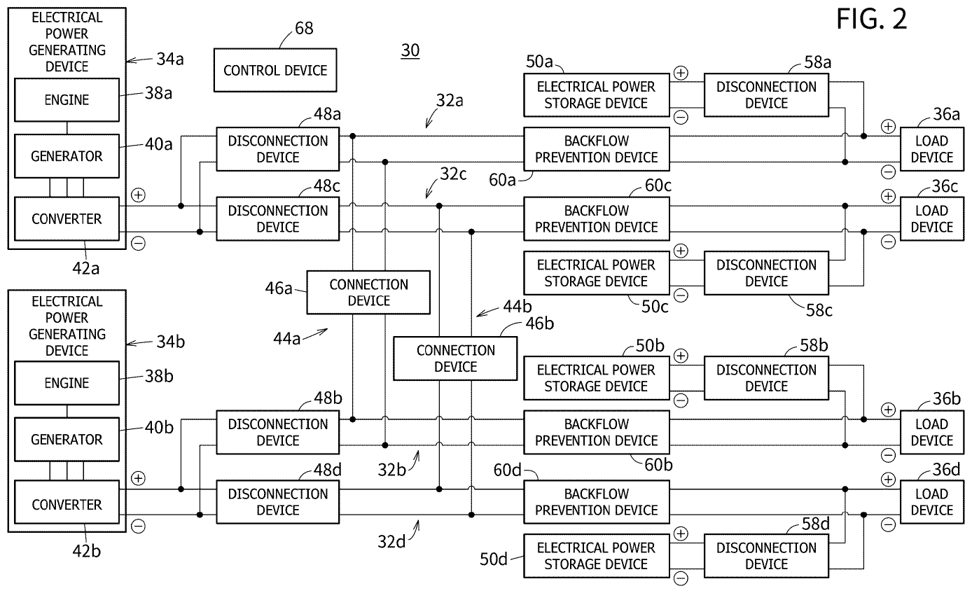

FIG. 2 is a schematic diagram of the electrical power supply system 30 according to the one embodiment. As shown in FIG. 2, the electrical power supply system 30 includes a first electrical power supply circuit 32a, a second electrical power supply circuit 32b, a third electrical power supply circuit 32c, and a fourth electrical power supply circuit 32d. The first electrical power supply circuit 32a supplies, to a first load device 36a, a DC electrical power that is output from a first electrical power generating device 34a. The second electrical power supply circuit 32b supplies, to a second load device 36b, a DC electrical power that is output from a second electrical power generating device 34b. The third electrical power supply circuit 32c supplies, to a third load device 36c, the DC electrical power that is output from the first electrical power generating device 34a. The fourth electrical power supply circuit 32d supplies, to a fourth load device 36d, the DC electrical power that is output from the second electrical power generating device 34b.

The electrical power supply system 30 is equipped with the first electrical power generating device 34a and the second electrical power generating device 34b. The first electrical power generating device 34a includes a first engine 38a, a first generator 40a, and a first converter 42a. The second electrical power generating device 34b includes a second engine 38b, a second generator 40b, and a second converter 42b. The first engine 38a and the second engine 38b, for example, are gas turbine engines. Moreover, the first engine 38a and the second engine 38b may be other engines such as reciprocating engines. The first generator 40a is driven by the first engine 38a and thereby generates a three-phase AC electrical power. The first converter 42a converts the three-phase AC electrical power that is output from the first generator 40a into a DC electrical power. The second generator 40b is driven by the second engine 38b and thereby generates a three-phase AC electrical power. The second converter 42b converts the three-phase AC electrical power that is output from the second generator 40b into a DC electrical power.

The first converter 42a and the second converter 42b may each include various sensors such as a voltage sensor and an electrical current sensor, and elements such as a fuse, a relay, a breaker, a diode, a transistor, a resistor, a coil, and a capacitor.

The electrical power supply system 30 is equipped with the first load device 36a, the second load device 36b, the third load device 36c, and the fourth load device 36d. Each of the first load device 36a, the second load device 36b, the third load device 36c, and the fourth load device 36d is equipped with two electric motors 16 and one electric motor 20. An inverter is connected to each of the two electric motors 16 and the electric motor 20. The inverter converts an input DC electrical power into a three-phase AC electrical power, and the electric motors 16 (or the electric motor 20) are driven by the three-phase AC electrical power. The first load device 36a, the second load device 36b, the third load device 36c, and the fourth load device 36d may each include a non-illustrated DC/DC converter and a low-voltage drive device. The DC/DC converter causes the voltage of the input DC electrical power to be reduced, and the low-voltage drive device is driven by the DC electrical power.

The first load device 36a, the second load device 36b, the third load device 36c, and the fourth load device 36d may each include various sensors such as a voltage sensor and an electrical current sensor, and elements such as a fuse, a relay, a breaker, a diode, a transistor, a resistor, a coil, and a capacitor. A plurality of the first load devices 36a may be connected in parallel to each other to the first electrical power supply circuit 32a. A plurality of the second load devices 36b may be connected in parallel to each other to the second electrical power supply circuit 32b. A plurality of the third load devices 36c may be connected in parallel to each other to the third electrical power supply circuit 32c. A plurality of the fourth load devices 36d may be connected in parallel to each other to the fourth electrical power supply circuit 32d.

The electrical power supply system 30 is equipped with a first connection circuit 44a and a second connection circuit 44b. The first connection circuit 44a is equipped with a first connection device 46a. The second connection circuit 44b is equipped with a second connection device 46b.

The first connection device 46a is capable of connecting the first electrical power supply circuit 32a and the second electrical power supply circuit 32b. The first connection device 46a is switched, by a non-illustrated contactor, between a state in which the first electrical power supply circuit 32a and the second electrical power supply circuit 32b are connected, and a state in which the first electrical power supply circuit 32a and the second electrical power supply circuit 32b are disconnected.

Similarly, the second connection device 46b is capable of connecting the third electrical power supply circuit 32c and the fourth electrical power supply circuit 32d. The second connection device 46b is switched, by a non-illustrated contactor, between a state in which the third electrical power supply circuit 32c and the fourth electrical power supply circuit 32d are connected, and a state in which the third electrical power supply circuit 32c and the fourth electrical power supply circuit 32d are disconnected.

The first connection device 46a and the second connection device 46b may each include a relay instead of the contactor. The first connection device 46a and the second connection device 46b may each include a breaker instead of the contactor. The first connection device 46a and the second connection device 46b may each include a semiconductor switch instead of the contactor.

Normally, the first electrical power supply circuit 32a and the second electrical power supply circuit 32b are disconnected. In accordance with this feature, in the case that an abnormality has occurred in one of the first electrical power supply circuit 32a or the second electrical power supply circuit 32b, it is possible to prevent the abnormality from adversely influencing the other one. For example, in the case that an excessive electrical current has been generated in one of the first electrical power supply circuit 32a or the second electrical power supply circuit 32b, the excessive electrical current is prevented from flowing to the other one.

In the same manner, normally, the third electrical power supply circuit 32c and the fourth electrical power supply circuit 32d are disconnected. In accordance with this feature, in the case that an abnormality has occurred in one of the third electrical power supply circuit 32c or the fourth electrical power supply circuit 32d, it is possible to prevent the abnormality from adversely influencing the other one. For example, in the case that an excessive electrical current has been generated in one of the third electrical power supply circuit 32c or the fourth electrical power supply circuit 32d, the excessive electrical current is prevented from flowing to the other one.

In the case that a problem has occurred in the supply of the electrical power from the first electrical power generating device 34a to the first electrical power supply circuit 32a, the first electrical power supply circuit 32a and the second electrical power supply circuit 32b are connected by the first connection device 46a. In accordance with this feature, the electrical power is supplied from the second electrical power supply circuit 32b to the first electrical power supply circuit 32a.

In the case that a problem has occurred in the supply of the electrical power from the first electrical power generating device 34a to the third electrical power supply circuit 32c, the third electrical power supply circuit 32c and the fourth electrical power supply circuit 32d are connected by the second connection device 46b. In accordance with this feature, the electrical power is supplied from the fourth electrical power supply circuit 32d to the third electrical power supply circuit 32c.

In the case that a problem has occurred in the supply of the electrical power from the second electrical power generating device 34b to the second electrical power supply circuit 32b, the first electrical power supply circuit 32a and the second electrical power supply circuit 32b are connected by the first connection device 46a. In accordance with this feature, the electrical power is supplied from the first electrical power supply circuit 32a to the second electrical power supply circuit 32b.

In the case that a problem has occurred in the supply of the electrical power from the second electrical power generating device 34b to the fourth electrical power supply circuit 32d, the third electrical power supply circuit 32c and the fourth electrical power supply circuit 32d are connected by the second connection device 46b. In accordance with this feature, the electrical power is supplied from the third electrical power supply circuit 32c to the fourth electrical power supply circuit 32d.

The electrical power supply system 30 is equipped with disconnection devices 48a to 48d. The disconnection device 48a is capable of disconnecting the first electrical power generating device 34a from the first electrical power supply circuit 32a and the first connection circuit 44a. The disconnection device 48b is capable of disconnecting the second electrical power generating device 34b from the second electrical power supply circuit 32b and the first connection circuit 44a. The disconnection device 48c is capable of disconnecting the first electrical power generating device 34a from the third electrical power supply circuit 32c and the second connection circuit 44b. The disconnection device 48d is capable of disconnecting the second electrical power generating device 34b from the fourth electrical power supply circuit 32d and the second connection circuit 44b.

The disconnection device 48a is switched, by a non-illustrated contactor, between a state in which the first electrical power generating device 34a is disconnected from the first electrical power supply circuit 32a and the first connection circuit 44a, and a state in which the first electrical power generating device 34a is connected to the first electrical power supply circuit 32a and the first connection circuit 44a. Similarly, the disconnection device 48b is switched, by a non-illustrated contactor, between a state in which the second electrical power generating device 34b is disconnected from the second electrical power supply circuit 32b and the first connection circuit 44a, and a state in which the second electrical power generating device 34b is connected to the second electrical power supply circuit 32b and the first connection circuit 44a.

Further, the disconnection device 48c is switched, by a non-illustrated contactor, between a state in which the first electrical power generating device 34a is disconnected from the third electrical power supply circuit 32c and the second connection circuit 44b, and a state in which the first electrical power generating device 34a is connected to the third electrical power supply circuit 32c and the second connection circuit 44b. Similarly, the disconnection device 48d is switched, by a non-illustrated contactor, between a state in which the second electrical power generating device 34b is disconnected from the fourth electrical power supply circuit 32d and the second connection circuit 44b, and a state in which the second electrical power generating device 34b is connected to the fourth electrical power supply circuit 32d and the second connection circuit 44b.

The disconnection devices 48a to 48d may each include a relay instead of the contactor. The disconnection devices 48a to 48d may each include a breaker instead of the contactor. The disconnection devices 48a to 48d may each include a semiconductor switch instead of the contactor.

The electrical power supply system 30 is equipped with a first electrical power storage device 50a, a second electrical power storage device 50b, a third electrical power storage device 50c, and a fourth electrical power storage device 50d. The first electrical power storage device 50a is connected to the first electrical power supply circuit 32a in parallel with the first electrical power generating device 34a. The second electrical power storage device 50b is connected to the second electrical power supply circuit 32b in parallel with the second electrical power generating device 34b. The third electrical power storage device 50c is connected to the third electrical power supply circuit 32c in parallel with the first electrical power generating device 34a. The fourth electrical power storage device 50d is connected to the fourth electrical power supply circuit 32d in parallel with the second electrical power generating device 34b.

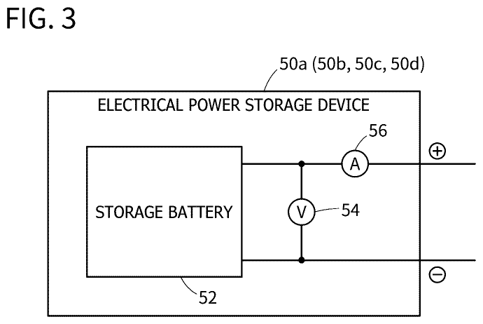

FIG. 3 is a schematic diagram illustrating an example of the first electrical power storage device 50a according to the one embodiment. As shown in FIG. 3, the second electrical power storage device 50b, the third electrical power storage device 50c, and the fourth electrical power storage device 50d have the same configuration as the first electrical power storage device 50a. The first electrical power storage device 50a includes a storage battery 52. The storage battery 52 may be, for example, a lithium ion battery or another type of battery. The first electrical power storage device 50a, the second electrical power storage device 50b, the third electrical power storage device 50c, and the fourth electrical power storage device 50d may each include a large-capacity capacitor instead of the storage battery 52.

The first electrical power storage device 50a includes a voltage sensor 54 and an electrical current sensor 56. The voltage sensor 54 is connected to a positive terminal and a negative terminal of the storage battery 52. The voltage sensor 54 measures a potential difference between the terminals of the storage battery 52. The electrical current sensor 56 is disposed on a positive wire that is connected to the positive terminal of the storage battery 52 or on a negative wire that is connected to the negative terminal of the storage battery 52. The electrical current sensor 56 measures the electrical current that flows through the positive wire or the negative wire.

The first electrical power storage device 50a, the second electrical power storage device 50b, the third electrical power storage device 50c, and the fourth electrical power storage device 50d may each include various other sensors, and elements such as a fuse, a relay, a breaker, a diode, a transistor, a resistor, a coil, and a capacitor.

The electrical power supply system 30 is equipped with disconnection devices 58a to 58d. The disconnection device 58a is capable of disconnecting the first electrical power storage device 50a from the first electrical power supply circuit 32a and the first load device 36a. The disconnection device 58b is capable of disconnecting the second electrical power storage device 50b from the second electrical power supply circuit 32b and the second load device 36b. The disconnection device 58c is capable of disconnecting the third electrical power storage device 50c from the third electrical power supply circuit 32c and the third load device 36c. The disconnection device 58d is capable of disconnecting the fourth electrical power storage device 50d from the fourth electrical power supply circuit 32d and the fourth load device 36d.

The disconnection device 58a is switched, by a non-illustrated contactor, between a state in which the first electrical power storage device 50a is disconnected from the first electrical power supply circuit 32a and the first load device 36a, and a state in which the first electrical power storage device 50a is connected to the first electrical power supply circuit 32a and the first load device 36a. Similarly, the disconnection device 58b is switched, by a non-illustrated contactor, between a state in which the second electrical power storage device 50b is disconnected from the second electrical power supply circuit 32b and the second load device 36b, and a state in which the second electrical power storage device 50b is connected to the second electrical power supply circuit 32b and the second load device 36b.

Further, the disconnection device 58c is switched, by a non-illustrated contactor, between a state in which the third electrical power storage device 50c is disconnected from the third electrical power supply circuit 32c and the third load device 36c, and a state in which the third electrical power storage device 50c is connected to the third electrical power supply circuit 32c and the third load device 36c. Similarly, the disconnection device 58d is switched, by a non-illustrated contactor, between a state in which the fourth electrical power storage device 50d is disconnected from the fourth electrical power supply circuit 32d and the fourth load device 36d, and a state in which the fourth electrical power storage device 50d is connected to the fourth electrical power supply circuit 32d and the fourth load device 36d.

The disconnection devices 58a to 58d may each include a relay instead of the contactor. The disconnection devices 58a to 58d may each include a breaker instead of the contactor. The disconnection devices 58a to 58d may each include a semiconductor switch instead of the contactor.

The electrical power supply system 30 is equipped with backflow prevention devices 60a to 60d. The backflow prevention device 60a limits the supply of the electrical power from the first electrical power storage device 50a to the first electrical power supply circuit 32a and the first electrical power generating device 34a. The backflow prevention device 60b limits the supply of the electrical power from the second electrical power storage device 50b to the second electrical power supply circuit 32b and the second electrical power generating device 34b. The backflow prevention device 60c limits the supply of the electrical power from the third electrical power storage device 50c to the third electrical power supply circuit 32c and the first electrical power generating device 34a. The backflow prevention device 60d limits the supply of the electrical power from the fourth electrical power storage device 50d to the fourth electrical power supply circuit 32d and the second electrical power generating device 34b.

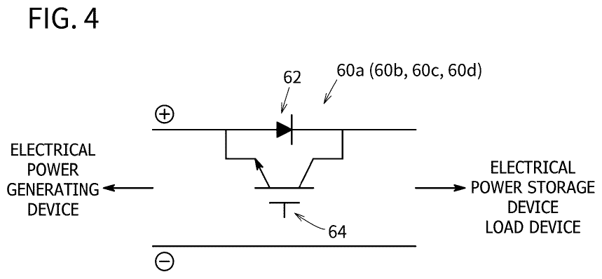

FIG. 4 is a schematic diagram illustrating an example of the backflow prevention device 60a according to the one embodiment. As shown in FIG. 4, the backflow prevention devices 60b to 60d have the same configuration as the backflow prevention device 60a. The backflow prevention device 60a includes, for example, a diode 62 and a transistor 64.

The diode 62 is provided in a positive wire. In the case that the voltage of the anode is lower than the voltage of the cathode, almost no electrical current flows through the diode 62. In the case that the voltage of the anode has become higher than the voltage of the cathode by more than the forward voltage, an electrical current flows through the diode 62. In accordance with this feature, an electrical power is supplied via the diode 62 from the first electrical power generating device 34a to the first load device 36a and the first electrical power storage device 50a.

The transistor 64 is disposed so as to bypass the diode 62. In the case that an electrical current flows from the base to the emitter of the transistor 64, the electrical current flows from the collector to the emitter. In accordance with this feature, the electrical power becomes capable of being supplied via the first electrical power supply circuit 32a from the first electrical power storage device 50a to the first connection circuit 44a. The diode 62 may be provided in a negative wire. Further, the diode 62 may be provided in both the positive wire and the negative wire.

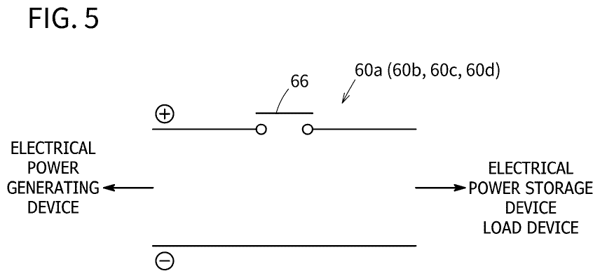

Moreover, the backflow prevention device 60a may be provided with only the diode 62, and may not be provided with the transistor 64. Further, as shown in FIG. 5, the backflow prevention device 60a may also include a switching device such as a contactor 66. The contactor 66 is disposed in at least one of the positive wire or the negative wire.

In addition to the configuration described above, the electrical power supply system 30 may include various sensors such as a voltage sensor and an electrical current sensor, and elements such as a fuse, a resistor, a coil, and a capacitor.

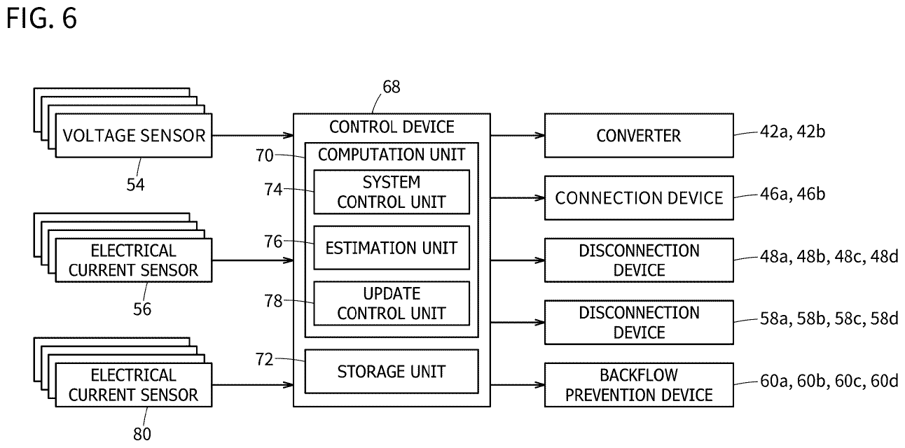

FIG. 6 is a control block diagram of a control device 68 according to the one embodiment. The electrical power supply system 30 is equipped with the control device 68. The control device 68 controls the first converter 42a, the second converter 42b, the first connection device 46a, the second connection device 46b, the disconnection devices 48a to 48d, the disconnection devices 58a to 58d, and the backflow prevention devices 60a to 60d.

The control device 68 includes a computation unit 70 and a storage unit 72. The computation unit 70 is a processor such as a central processing unit (CPU) or a graphics processing unit (GPU). The computation unit 70 includes a system control unit 74, an estimation unit 76, and an update control unit 78. The system control unit 74, the estimation unit 76, and the update control unit 78 are realized by the computation unit 70 executing a program that is stored in the storage unit 72. At least a portion of the system control unit 74, the estimation unit 76, and the update control unit 78 may be realized by an integrated circuit such as an application specific integrated circuit (ASIC) or a field-programmable gate array (FPGA). Alternatively, at least a portion of the system control unit 74, the estimation unit 76, and the update control unit 78 may be realized by an electronic circuit including a discrete device.

The storage unit 72 is a computer-readable non-transitory tangible storage medium. The storage unit 72 is constituted by a non-illustrated volatile memory and a non-illustrated non-volatile memory. The volatile memory, for example, is a random access memory (RAM) or the like. The non-volatile memory, for example, is a read only memory (ROM), a flash memory, or the like. Data and the like are stored, for example, in the volatile memory. A program, a table, a map, and the like are stored, for example, in the non-volatile memory. At least a portion of the storage unit 72 may be provided in the processor, the integrated circuit, or the like described above.

The system control unit 74 executes various processes and various controls of the electrical power supply system 30. For example, the system control unit 74 executes an opening and closing control (an ON/OFF control) of the first converter 42a, the second converter 42b, the first connection device 46a, the second connection device 46b, the disconnection devices 48a to 48d, the disconnection devices 58a to 58d, and the transistors 64 (or the contactors 66) of the backflow prevention devices 60a to 60d. On the other hand, the estimation unit 76 and the update control unit 78 execute processes and controls for the purpose of acquiring the residual capacity of each of the electrical power storage devices (50a to 50d).

The estimation unit 76, based on the amount of electrical power that is charged and discharged by the first electrical power storage device 50a, estimates the residual capacity (a first residual capacity) of the first electrical power storage device 50a. For example, the estimation unit 76 calculates the first residual capacity by an electrical current integration method. The estimation unit 76, in the same manner as estimating the first residual capacity, estimates the residual capacity (a second residual capacity) of the second electrical power storage device 50b, the residual capacity (a third residual capacity) of the third electrical power storage device 50c, and the residual capacity (a fourth residual capacity) of the fourth electrical power storage device 50d. The residual capacities of the electrical power storage devices that are estimated by the estimation unit 76 are referred to as residual capacity estimated values (a first residual capacity estimated value, a second residual capacity estimated value, a third residual capacity estimated value, and a fourth residual capacity estimated value).

When a predetermined timing has arrived, based on the open circuit voltage of the first electrical power storage device 50a, the update control unit 78 updates the first residual capacity estimated value that was estimated by the estimation unit 76. For example, the update control unit 78, by an open-circuit voltage method, acquires a theoretical value of the residual capacity of the first electrical power storage device 50a, and updates the first residual capacity estimated value using the theoretical value. The update control unit 78, in the same manner as updating the first residual capacity estimated value, updates the second residual capacity estimated value, the third residual capacity estimated value, and the fourth residual capacity estimated value. When updating the residual capacity estimated values of the electrical power storage devices, the update control unit 78 executes the opening and closing control (the ON/OFF control) of the first connection device 46a, the second connection device 46b, the disconnection devices 58a to 58d, and the transistors 64 (or the contactors 66) of the backflow prevention devices 60a to 60d.

### Operations of Electrical Power Supply System 30

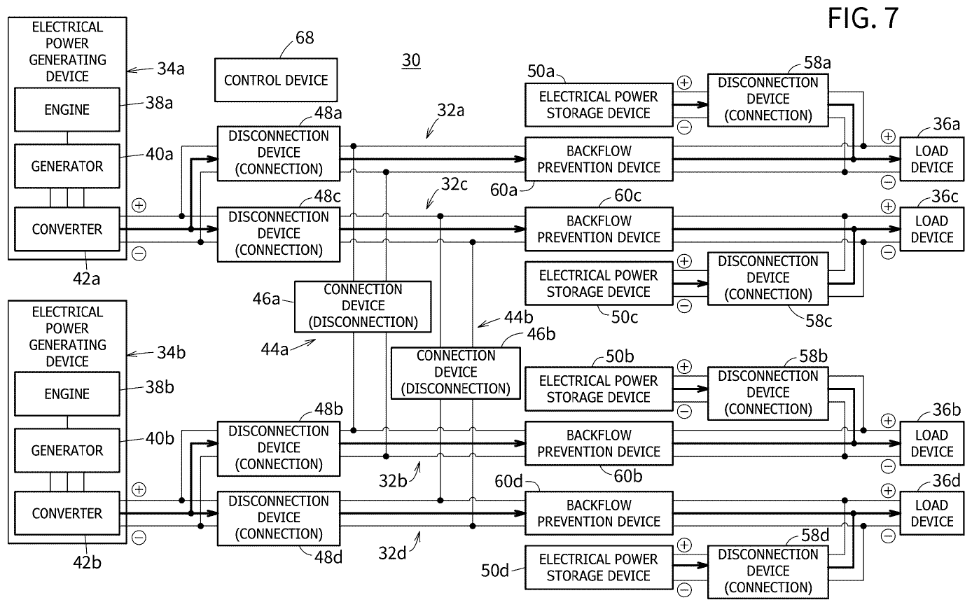

FIG. 7 is a diagram showing operations of the electrical power supply system 30 at a normal time in the one embodiment. The arrows shown in FIG. 7 indicate electrical power supply pathways. In the following description, the system control unit 74 executes the control of the first converter 42a, the second converter 42b, the first connection device 46a, the second connection device 46b, the disconnection devices 48a to 48d, and the disconnection devices 58a to 58d.

As shown in FIG. 7, the first electrical power generating device 34a is connected to the first electrical power supply circuit 32a by the disconnection device 48a, and the first electrical power generating device 34a is connected to the third electrical power supply circuit 32c by the disconnection device 48c. In accordance with this feature, the three-phase AC electrical power that is output from the first generator 40a is converted into a DC electrical power by the first converter 42a, and the DC electrical power is supplied to the first load device 36a and the third load device 36c.

The second electrical power generating device 34b is connected to the second electrical power supply circuit 32b by the disconnection device 48b, and the second electrical power generating device 34b is connected to the fourth electrical power supply circuit 32d by the disconnection device 48d. In accordance with this feature, the three-phase AC electrical power that is output from the second generator 40b is converted into a DC electrical power by the second converter 42b, and the DC electrical power is supplied to the second load device 36b and the fourth load device 36d.

The first electrical power storage device 50a is connected to the first load device 36a by the disconnection device 58a. In accordance with this feature, the DC electrical power that is output from the first electrical power storage device 50a is supplied to the first load device 36a. The second electrical power storage device 50b is connected to the second load device 36b by the disconnection device 58b. In accordance with this feature, the DC electrical power that is output from the second electrical power storage device 50b is supplied to the second load device 36b. The third electrical power storage device 50c is connected to the third load device 36c by the disconnection device 58c. In accordance with this feature, the DC electrical power that is output from the third electrical power storage device 50c is supplied to the third load device 36c. The fourth electrical power storage device 50d is connected to the fourth load device 36d by the disconnection device 58d. In accordance with this feature, the DC electrical power that is output from the fourth electrical power storage device 50d is supplied to the fourth load device 36d.

At a normal time, the first electrical power supply circuit 32a and the second electrical power supply circuit 32b are disconnected by the first connection device 46a, and the third electrical power supply circuit 32c and the fourth electrical power supply circuit 32d are disconnected by the second connection device 46b.

When an abnormality occurs in the first electrical power generating device 34a or the second electrical power generating device 34b, the first electrical power supply circuit 32a and the second electrical power supply circuit 32b can be connected by the first connection device 46a. Similarly, when an abnormality or the like occurs in the first electrical power generating device 34a or the second electrical power generating device 34b, the third electrical power supply circuit 32c and the fourth electrical power supply circuit 32d can be connected by the second connection device 46b. In accordance with this feature, the three-phase AC electrical power that is output from the first generator 40a is converted into a DC electrical power by the first converter 42a, and the DC electrical power can be supplied to the second load device 36b and the fourth load device 36d. Alternatively, the three-phase AC electrical power that is output from the second generator 40b is converted into a DC electrical power by the second converter 42b, and the DC electrical power can be supplied to the first load device 36a and the third load device 36c.

### Process for Acquiring Residual Capacity of Electrical Power Storage Devices

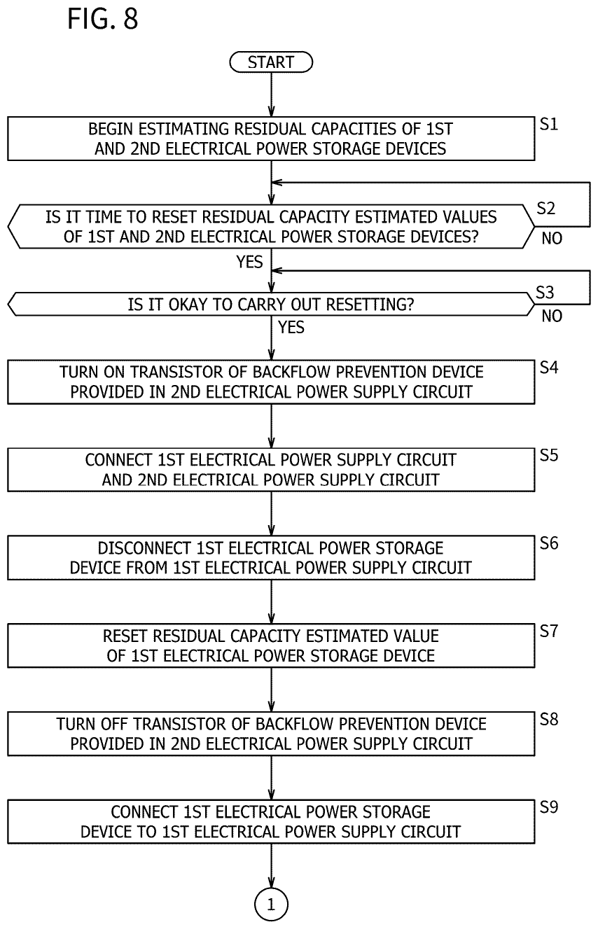

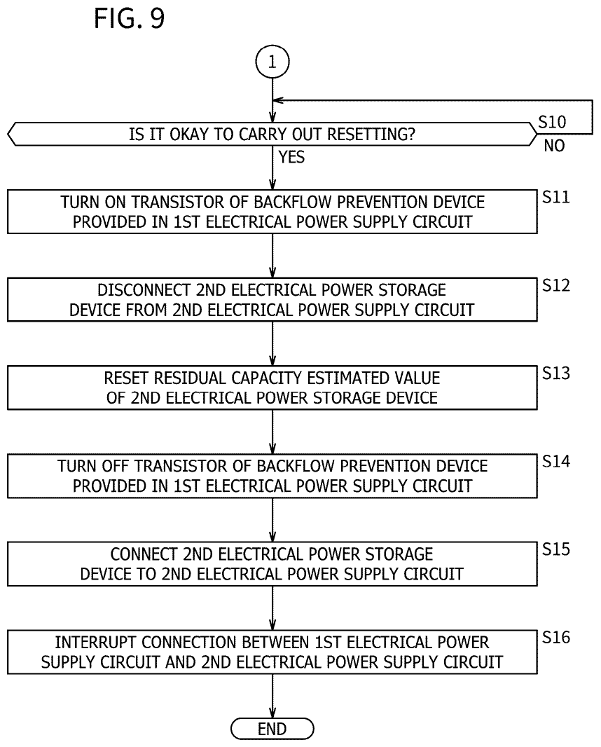

FIG. 8 and FIG. 9 are flowcharts of the process for acquiring the residual capacity. FIG. 8 and FIG. 9 show a process for acquiring the residual capacity of the first electrical power storage device 50a and the residual capacity of the second electrical power storage device 50b that are capable of being connected by the first connection device 46a.

The first electrical power supply circuit 32a, to which the first electrical power storage device 50a is connected, can be connected via the first connection device 46a to the second electrical power supply circuit 32b, to which the second electrical power storage device 50b is connected. Stated otherwise, in addition to the first electrical power storage device 50a, the second electrical power storage device 50b is capable of supplying the electrical power via the first connection device 46a to the first load device 36a that is connected to the first electrical power supply circuit 32a. Similarly, in addition to the second electrical power storage device 50b, the first electrical power storage device 50a is capable of supplying the electrical power via the first connection device 46a to the second load device 36b that is connected to the second electrical power supply circuit 32b. The estimation unit 76 and the update control unit 78 of the computation unit 70 carry out the residual capacity acquisition process described below on the plurality of electrical power storage devices that are capable of supplying the electrical power to one of the load devices.

During a flight of the moving object 10, the estimation unit 76 and the update control unit 78 acquire the latest residual capacity estimated value of the first electrical power storage device 50a and the latest residual capacity estimated value of the second electrical power storage device 50b by executing the residual capacity acquisition process shown in FIG. 8 and FIG. 9. During a single flight of the moving object 10, the estimation unit 76 and the update control unit 78 may carry out the residual capacity acquisition process shown in FIG. 8 and FIG. 9 one time or a plurality of times.

In step S1, the estimation unit 76 of the computation unit 70 begins estimating the residual capacity of the first electrical power storage device 50a and the residual capacity of the second electrical power storage device 50b. For example, at every first predetermined time period, the estimation unit 76 estimates the residual capacity of the first electrical power storage device 50a based on the amount of electrical power that is charged and discharged by the first electrical power storage device 50a. The estimation unit 76 estimates the residual capacity of the first electrical power storage device 50a by an electrical current integration method. For example, the estimation unit 76 calculates the residual capacity estimated value of the first electrical power storage device 50a, based on the residual capacity estimated value of the first electrical power storage device 50a (the storage battery 52) that is acquired by a previous estimation, the capacity (a fully charged capacity) of the first electrical power storage device 50a (the storage battery 52), and a time integral value of the measurement value of the electrical current sensor 56 provided in the first electrical power storage device 50a. The time integral value of the measurement value of the electrical current sensor 56 is an integrated value of the electrical current measured by the electrical current sensor 56 from a previous estimation until a current estimation. Every time that the estimation unit 76 calculates the residual capacity estimated value of the first electrical power storage device 50a, the estimation unit 76 stores the calculated residual capacity estimated value in the storage unit 72. The estimation unit 76 estimates the residual capacity of the second electrical power storage device 50b in the same manner as the estimation of the residual capacity of the first electrical power storage device 50a.

In step S2, the update control unit 78 of the computation unit 70 determines whether or not a timing has arrived to eliminate errors contained respectively in the residual capacity estimated value of the first electrical power storage device 50a and the residual capacity estimated value of the second electrical power storage device 50b. More specifically, the update control unit 78 of the computation unit 70 determines whether or not a timing has arrived to reset the residual capacity estimated value of the first electrical power storage device 50a and the residual capacity estimated value of the second electrical power storage device 50b. By measuring again the open circuit voltages of the first electrical power storage device 50a and the second electrical power storage device 50b, resetting of the residual capacity estimated values of the electrical power storage devices is carried out. In the present embodiment, the timing at which the resetting of the residual capacity estimated values of the electrical power storage devices is carried out is set to a point in time at which a second predetermined time period (which is longer than the first predetermined time period) has elapsed since the moving object 10 started flying. In the case that the timing has arrived to reset the residual capacity estimated values of the electrical power storage devices (step S2: YES), the process transitions to step S3. On the other hand, in the case that the timing has not arrived to reset the residual capacity estimated values of the electrical power storage devices (step S2: NO), the process of step S2 is executed again.

In the case that a timing has arrived to reset the residual capacity estimated value of each of the electrical power storage devices, a series of processes (step S3 to step S9) in relation to the resetting of the residual capacity estimated value of the first electrical power storage device 50a are started.

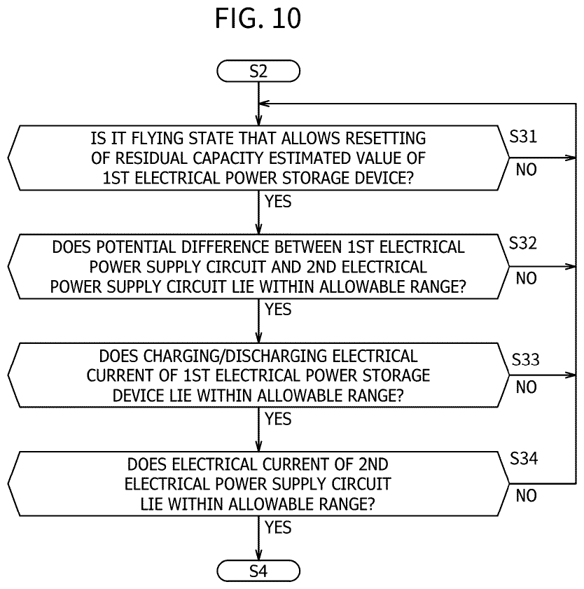

In step S3, the update control unit 78 determines whether or not to reset the residual capacity estimated value of the first electrical power storage device 50a. In this instance, the update control unit 78 carries out a state determination process for determining whether or not the moving object 10 and the electrical power supply system 30 are in a state that allows various controls for resetting the residual capacity estimated value of the first electrical power storage device 50a to be executed. FIG. 10 shows an example of the state determination process. Hereinafter, the state determination process will be described with reference to FIG. 10.

In step S31, the update control unit 78 determines whether or not the flying state is a state that allows the resetting of the residual capacity estimated value of the first electrical power storage device 50a to be carried out. When resetting the residual capacity estimated value of the first electrical power storage device 50a, the update control unit 78 disconnects the first electrical power storage device 50a from the first electrical power supply circuit 32a using the disconnection device 58a (step S6 of FIG. 8). Stated otherwise, when the residual capacity estimated value of the first electrical power storage device 50a is reset, the electrical power supply capacity of the electrical power supply system 30 temporarily decreases. For this purpose, it is preferable to reset the residual capacity estimated value of the first electrical power storage device 50a when the electrical power supply system 30 has a surplus electrical power supply capacity. In other words, it is preferable to reset the residual capacity estimated value of the first electrical power storage device 50a when the amount of electrical power required by the moving object 10 is small. In the case that the moving object 10 is an eVTOL aircraft, the overall electrical power consumption of the eight electric motors 16 and the four electric motors 20 is relatively low during cruising. Accordingly, in the present embodiment, in the case that the moving object 10 is cruising, the update control unit 78 resets the residual capacity estimated value of the first electrical power storage device 50a. Information indicating the flying state of the moving object 10 is stored sequentially in the storage unit 72. The update control unit 78, based on the information indicating the flying state of the moving object 10, determines the flying state of the moving object 10.

In the case that the flying state of the moving object 10 is a cruising state, and more specifically, in the case that the flying state is the state that allows the resetting of the residual capacity estimated value of the first electrical power storage device 50a to be carried out (step S31: YES), the process transitions to step S32. On the other hand, in the case that the flying state of the moving object 10 is not a cruising state, and more specifically, in the case that the flying state is not the state that allows the resetting of the residual capacity estimated value of the first electrical power storage device 50a to be carried out (step S31: NO), the process of step S31 is executed again.

When the process transitions from step S31 to step S32, the update control unit 78 determines whether or not the potential difference between the first electrical power supply circuit 32a and the second electrical power supply circuit 32b (hereinafter referred to as a potential difference V1) lies within an allowable range. When resetting the residual capacity estimated value of the first electrical power storage device 50a, the update control unit 78 connects the first electrical power supply circuit 32a and the second electrical power supply circuit 32b using the first connection device 46a (step S5 of FIG. 8). If the first electrical power supply circuit 32a and the second electrical power supply circuit 32b are connected by the first connection device 46a when the potential difference V1 lies outside of the allowable range, there is a concern in that sparks may be generated in the first connection device 46a. Further, there is a concern in that a large current flowing from one of the circuits to the other of the circuits may occur. As a result, there is a concern in that the circuitry may be damaged. In order to avoid such a problem, in the case that the potential difference V1 lies outside of the allowable range, the update control unit 78 does not carry out the resetting of the residual capacity estimated value of the first electrical power storage device 50a. The update control unit 78, for example, acquires a measurement value of the voltage sensor 54 that is provided in the first electrical power storage device 50a, as the voltage value of the first electrical power supply circuit 32a. Further, the update control unit 78, for example, acquires a measurement value of the voltage sensor 54 that is provided in the second electrical power storage device 50b, as the voltage value of the second electrical power supply circuit 32b. The update control unit 78 determines whether or not the potential difference V1, which is a difference between the two voltage values, is less than or equal to a potential difference threshold value V1th that is stored in advance in the storage unit 72.

In the case that the potential difference V1 is less than or equal to the potential difference threshold value V1th, and more specifically, in the case that the potential difference V1 lies within the allowable range (step S32: YES), the process transitions to step S33. On the other hand, in the case that the potential difference V1 exceeds the potential difference threshold value V1th, and more specifically, in the case that the potential difference V1 lies outside of the allowable range (step S32: NO), the process returns to step S31.

When the process transitions from step S32 to step S33, the update control unit 78 determines whether or not a charging/discharging electrical current of the first electrical power storage device 50a lies within an allowable range. As noted previously, when resetting the residual capacity estimated value of the first electrical power storage device 50a, the update control unit 78 disconnects the first electrical power storage device 50a from the first electrical power supply circuit 32a using the disconnection device 58a. If the first electrical power storage device 50a is disconnected from the first electrical power supply circuit 32a by the disconnection device 58a when the charging/discharging electrical current of the first electrical power storage device 50a lies outside of the allowable range, there is a concern in that sparks may be generated in the disconnection device 58a. As a result, there is a concern in that the circuitry may be damaged. In order to avoid such a problem, in the case that the charging/discharging electrical current of the first electrical power storage device 50a lies outside of the allowable range, the update control unit 78 does not carry out the resetting of the residual capacity estimated value of the first electrical power storage device 50a. The update control unit 78, for example, determines whether or not an electrical current value I1, which is a measurement value of the electrical current sensor 56 provided in the first electrical power storage device 50a, is less than or equal to an electrical current threshold value I1th that is stored in advance in the storage unit 72.

In the case that the electrical current value I1 is less than or equal to the electrical current threshold value I1th, and more specifically, in the case that the charging/discharging electrical current of the first electrical power storage device 50a lies within the allowable range (step S33: YES), the process transitions to step S34. On the other hand, in the case that the electrical current value I1 exceeds the electrical current threshold value I1th, and more specifically, in the case that the charging/discharging electrical current of the first electrical power storage device 50a lies outside of the allowable range (step S33: NO), the process returns to step S31.

When the process transitions from step S33 to step S34, the update control unit 78 determines whether or not the electrical current of the second electrical power supply circuit 32b lies within an allowable range. When resetting the residual capacity estimated value of the first electrical power storage device 50a, the update control unit 78 turns ON the transistor 64 of the backflow prevention device 60b that is provided in the second electrical power supply circuit 32b (step S4 of FIG. 8). If the transistor 64 of the backflow prevention device 60b is turned ON when the electrical current of the second electrical power supply circuit 32b lies outside of the allowable range, there is a concern in that a large electrical current may flow to the transistor 64. As a result, there is a concern in that the transistor 64 may be damaged. In order to avoid such a problem, in the case that the electrical current of the second electrical power supply circuit 32b lies outside of the allowable range, the update control unit 78 does not carry out the resetting of the residual capacity estimated value of the first electrical power storage device 50a. The update control unit 78, for example, determines whether or not an electrical current value I2, which is a measurement value of an electrical current sensor 80 (refer to FIG. 6) provided in the second electrical power supply circuit 32b, is less than or equal to an electrical current threshold value I2th that is stored in advance in the storage unit 72.

In the case that the electrical current value I2 is less than or equal to the electrical current threshold value I2th, and more specifically, in the case that the electrical current of the second electrical power supply circuit 32b lies within the allowable range (step S34: YES), the process transitions to step S4 shown in FIG. 8. On the other hand, in the case that the electrical current value I2 exceeds the electrical current threshold value I2th, and more specifically, in the case that the electrical current of the second electrical power supply circuit 32b lies outside of the allowable range (step S34: NO), the process returns to step S31.

When the process transitions from step S34 shown in FIG. 10 to step S4 shown in FIG. 8, the update control unit 78 turns ON the transistor 64 of the backflow prevention device 60b that is provided in the second electrical power supply circuit 32b.

In step S5, the update control unit 78 connects the first electrical power supply circuit 32a and the second electrical power supply circuit 32b using the first connection device 46a. By step S4 and step S5 being executed, an electrical power supply circuit from the second electrical power storage device 50b to the first load device 36a is formed. At this time, the second electrical power storage device 50b is connected, via the first connection circuit 44a and the second electrical power supply circuit 32b, to the first electrical power supply circuit 32a.

In step S6, the update control unit 78 disconnects the first electrical power storage device 50a from the first electrical power supply circuit 32a using the disconnection device 58a. In accordance with this feature, it becomes possible to measure the open circuit voltage of the first electrical power storage device 50a.

In step S7, the update control unit 78 resets the residual capacity estimated value of the first electrical power storage device 50a, based on the open circuit voltage of the first electrical power storage device 50a and first conversion information that is stored in advance in the storage unit 72. The first conversion information is information that associates the open circuit voltage of the first electrical power storage device 50a with a theoretical residual capacity value that corresponds to the open circuit voltage. The update control unit 78 acquires the theoretical residual capacity value of the first electrical power storage device 50a, based on the measurement value of the voltage sensor 54 that is provided in the first electrical power storage device 50a, and the first conversion information that is stored in the storage unit 72. The update control unit 78 replaces the latest residual capacity estimated value of the first electrical power storage device 50a that is stored in the storage unit 72 with the theoretical residual capacity value that is acquired from the first conversion information. In this manner, the update control unit 78 updates the residual capacity estimated value of the first electrical power storage device 50a based on the open circuit voltage of the first electrical power storage device 50a.

In step S8, the update control unit 78 turns OFF the transistor 64 of the backflow prevention device 60b that is provided in the second electrical power supply circuit 32b.

In step S9, the update control unit 78 connects the first electrical power storage device 50a to the first electrical power supply circuit 32a using the disconnection device 58a. When the process of step S9 is completed, an ordinary electrical power supply pathway is temporarily formed in the electrical power supply system 30, except that the first electrical power supply circuit 32a and the second electrical power supply circuit 32b are connected via the first connection device 46a. From this state, a series of processes (step S10 to step S15 of FIG. 9) in relation to the resetting of the residual capacity estimated value of the second electrical power storage device 50b are started.

In step S10, the update control unit 78 determines whether or not to reset the residual capacity estimated value of the second electrical power storage device 50b. In this instance, the update control unit 78 carries out a state determination process for determining whether or not the moving object 10 and the electrical power supply system 30 are in a state that allows various controls for resetting the residual capacity estimated value of the second electrical power storage device 50b to be executed.

The state determination process that is executed in step S10 corresponds to the state determination process that is executed in step S3. Concerning the state determination process that is executed in step S10, the subject and the object in the description of step S31 to step S34 in FIG. 10 may be exchanged. For example, the “first electrical power storage device 50a” in the description may be read as the “second electrical power storage device 50b.” Further, the “second electrical power storage device 50b” in the description may be read as the “first electrical power storage device 50a.” Further, the “first electrical power supply circuit 32a” in the description may be read as the “second electrical power supply circuit 32b.” Further, the “second electrical power supply circuit 32b” in the description may be read as the “first electrical power supply circuit 32a.” Further, the “disconnection device 58a” in the description may be read as the “disconnection device 58b.” Further, the “backflow prevention device 60b” in the description may be read as the “backflow prevention device 60a.”

Moreover, at this point in time, the first electrical power supply circuit 32a and the second electrical power supply circuit 32b are already connected by the first connection device 46a. Therefore, in step S10, the update control unit 78 does not need to execute the process corresponding to step S32 shown in FIG. 10.

When the process transitions from step S10 to step S11, the update control unit 78 turns ON the transistor 64 of the backflow prevention device 60a that is provided in the first electrical power supply circuit 32a. In accordance with this feature, an electrical power supply circuit from the first electrical power storage device 50a to the second load device 36b is formed. At this time, the first electrical power storage device 50a is connected, via the first connection circuit 44a and the first electrical power supply circuit 32a, to the second electrical power supply circuit 32b.

In step S12, the update control unit 78 disconnects the second electrical power storage device 50b from the second electrical power supply circuit 32b using the disconnection device 58b. In accordance with this feature, it becomes possible to measure the open circuit voltage of the second electrical power storage device 50b.

In step S13, the update control unit 78 resets the residual capacity estimated value of the second electrical power storage device 50b, based on the open circuit voltage of the second electrical power storage device 50b and second conversion information that is stored in advance in the storage unit 72. The second conversion information is information that associates the open circuit voltage of the second electrical power storage device 50b with a theoretical residual capacity value that corresponds to the open circuit voltage. The update control unit 78 acquires the theoretical residual capacity value of the second electrical power storage device 50b, based on the measurement value of the voltage sensor 54 that is provided in the second electrical power storage device 50b, and the second conversion information that is stored in the storage unit 72. The update control unit 78 replaces the latest residual capacity estimated value of the second electrical power storage device 50b that is stored in the storage unit 72 with the theoretical residual capacity value that is acquired from the second conversion information. In this manner, the update control unit 78 updates the residual capacity estimated value of the second electrical power storage device 50b based on the open circuit voltage of the second electrical power storage device 50b.

In step S14, the update control unit 78 turns OFF the transistor 64 of the backflow prevention device 60a that is provided in the first electrical power supply circuit 32a.

In step S15, the update control unit 78 connects the second electrical power storage device 50b to the second electrical power supply circuit 32b using the disconnection device 58b.

In step S16, the update control unit 78 interrupts the connection between the first electrical power supply circuit 32a and the second electrical power supply circuit 32b using the first connection device 46a. When the process of step S16 is completed, the electrical power supply system 30 is placed in a normal electrical power supplying state.

The process of acquiring the residual capacity of the first electrical power storage device 50a and the residual capacity of the second electrical power storage device 50b has been described with reference to FIG. 8 to FIG. 10 thus far. Moreover, also in the case that the residual capacity of the third electrical power storage device 50c and the residual capacity of the fourth electrical power storage device 50d are acquired, the estimation unit 76 and the update control unit 78 carry out the residual capacity acquisition process in the same manner to that shown in FIG. 8 to FIG. 10. Concerning the residual capacity acquisition process for acquiring the residual capacity of the third electrical power storage device 50c and the residual capacity of the fourth electrical power storage device 50d, the subject and the object in the description made with reference to FIG. 8 to FIG. 10 may be exchanged. For example, the “first electrical power storage device 50a” in the description may be read as the “third electrical power storage device 50c.” Further, the “second electrical power storage device 50b” in the description may be read as the “fourth electrical power storage device 50d.” Further, the “first electrical power supply circuit 32a” in the description may be read as the “third electrical power supply circuit 32c.” Further, the “second electrical power supply circuit 32b” in the description may be read as the “fourth electrical power supply circuit 32d.” Further, the “first connection device 46a” in the description may be read as the “second connection device 46b.” Further, the “disconnection device 58a” in the description may be read as the “disconnection device 58c.” Further, the “disconnection device 58b” in the description may be read as the “disconnection device 58d.” Further, the “backflow prevention device 60a” in the description may be read as the “backflow prevention device 60c.” Further, the “backflow prevention device 60b” in the description may be read as the “backflow prevention device 60d.”

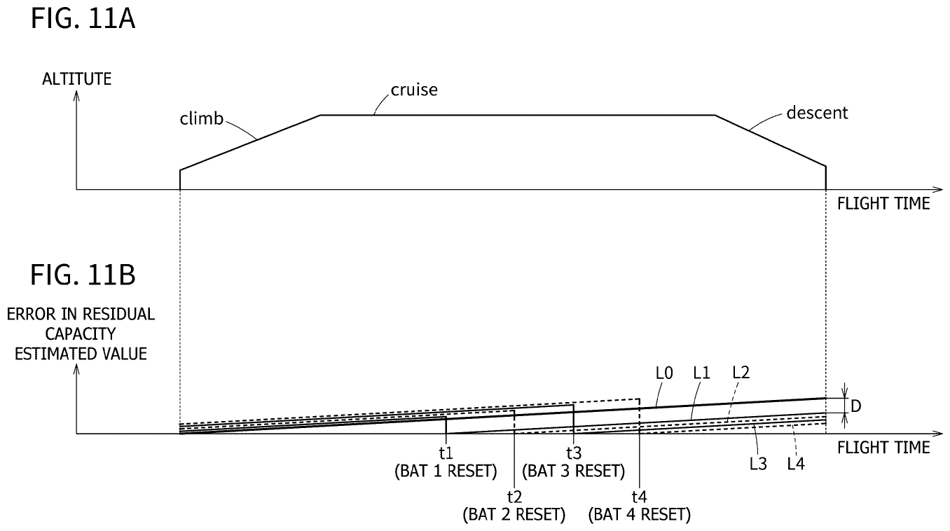

FIG. 11A is a diagram showing a relationship between a flight time of the moving object 10 and an altitude of the moving object 10. FIG. 11B is a diagram showing a relationship between the flight time of the moving object 10 and an error contained in the residual capacity estimated value of the electrical power storage device.

At a point in time t1 during cruising, a residual capacity estimated value (L1) of the first electrical power storage device 50a (BAT1) is reset. At a point in time t2 during cruising, a residual capacity estimated value (L2) of the second electrical power storage device 50b (BAT2) is reset. At a point in time t3 during cruising, a residual capacity estimated value (L3) of the third electrical power storage device 50c (BAT3) is reset. At a point in time t4 during cruising, a residual capacity estimated value (L4) of the fourth electrical power storage device 50d (BAT4) is reset. The error contained in the residual capacity estimated value (L1 to L4) in the case that resetting is carried out is smaller by D than the error contained in a residual capacity estimated value (L0) in the case that resetting is not carried out.

As shown in FIG. 11B, in the present embodiment, the resetting of the residual capacity estimated value of the third electrical power storage device 50c and the resetting of the residual capacity estimated value of the fourth electrical power storage device 50d are carried out after having carried out the resetting of the residual capacity estimated value of the first electrical power storage device 50a and the resetting of the residual capacity estimated value of the second electrical power storage device 50b. However, the resetting of the residual capacity estimated value of the first electrical power storage device 50a and the resetting of the residual capacity estimated value of the second electrical power storage device 50b may be carried out at the same timing as the resetting of the residual capacity estimated value of the third electrical power storage device 50c, and the resetting of the residual capacity estimated value of the fourth electrical power storage device 50d.

### Advantageous Effects of Present Embodiment

For example, in order to reset the residual capacity estimated value of the first electrical power storage device 50a, it is necessary to disconnect the first electrical power storage device 50a from the first load device 36a. When the first electrical power storage device 50a is disconnected from the first load device 36a, the first load device 36a can be supplied with the electrical power from the first generator 40a, but cannot be supplied with the electrical power from the first electrical power storage device 50a. In such a state, there is a concern in that a sufficient amount of electrical power cannot be supplied to the first load device 36a.

In the present embodiment, when resetting the residual capacity estimated value of the first electrical power storage device 50a, the update control unit 78 disconnects the first electrical power storage device 50a from the first load device 36a, and connects the second electrical power storage device 50b to the first load device 36a. In accordance with this feature, the electrical power becomes capable of being supplied from the first generator 40a and the second electrical power storage device 50b to the first load device 36a. According to the present embodiment, even if the first load device 36a requires a large amount of electrical power when the residual capacity estimated value of the first electrical power storage device 50a is being reset, the necessary electrical power can be supplied to the first load device 36a.

Resetting the residual capacity estimated values of the other electrical power storage devices (50b to 50d) also has the same effect as the resetting of the residual capacity estimated value of the first electrical power storage device 50a. More specifically, according to the present embodiment, even if the load devices (36a to 36d) require a large amount of electrical power when the residual capacity estimated values of the electrical power storage devices (50a to 50d) are being reset, the necessary electrical power can be supplied to the load devices (36a to 36d).

Further, in the present embodiment, the update control unit 78 carries out in succession the resetting of the residual capacity estimated value of the first electrical power storage device 50a and the resetting of the residual capacity estimated value of the second electrical power storage device 50b. Provisionally, in the case that the two resettings are not carried out in succession, the control for the first connection device 46a must be carried out one time before and one time after the resetting of the residual capacity estimated value of the first electrical power storage device 50a, and furthermore, one time before and one time after the resetting of the residual capacity estimated value of the second electrical power storage device 50b. In contrast thereto, according to the present embodiment, the update control unit 78 only needs to control the first connection device 46a one time before the resetting of the residual capacity estimated value of the first electrical power storage device 50a, and one time after the resetting of the residual capacity estimated value of the second electrical power storage device 50b. In this manner, according to the present embodiment, the number of times that the first connection device 46a is connected and disconnected can be reduced.

Similarly, in the present embodiment, since the update control unit 78 carries out in succession the resetting of the residual capacity estimated value of the third electrical power storage device 50c and the resetting of the residual capacity estimated value of the fourth electrical power storage device 50d, the number of times that the second connection device 46b is connected and disconnected can be reduced.

The following supplementary notes are further disclosed in relation to the above-described embodiment.

### Supplementary Note 1

The electrical power supply system (30) of the present disclosure includes: the first electrical power supply circuit (32a) that is connected to the first load device (36a); the second electrical power supply circuit (32b) that is connected to the second load device (36b); the first electrical power storage device (50a) that is connected via the first disconnection device (58a) to the first electrical power supply circuit; the second electrical power storage device (50b) that is connected via the second disconnection device (58b) to the second electrical power supply circuit; the first connection circuit (44a) including the first connection device (46a) that is capable of connecting the first electrical power supply circuit and the second electrical power supply circuit; the estimation unit (76) that is capable of estimating a first residual capacity, which is a residual capacity of the first electrical power storage device, based on an amount of electrical power that is charged and discharged by the first electrical power storage device; and the update control unit (78) which, in a state in which, by controlling the first connection device, the second electrical power storage device is connected via the first connection circuit and the second electrical power supply circuit to the first electrical power supply circuit, is capable of disconnecting the first electrical power storage device from the first electrical power supply circuit by controlling the first disconnection device, and is capable of updating a first residual capacity estimated value, which is the first residual capacity estimated by the estimation unit, based on an open circuit voltage of the first electrical power storage device.

In accordance with the above-described configuration, even if the first load device requires a large amount of electrical power when the first residual capacity estimated value of the first electrical power storage device is being reset, the necessary electrical power can be supplied to the first load device.

### Supplementary Note 2

The electrical power supply system according to Supplementary Note 1 may further include the first electrical power source (40a) that is connected to the first electrical power supply circuit and is capable of charging the first electrical power storage device.

### Supplementary Note 3

In the electrical power supply system according to Supplementary Note 2, the first electrical power source may be connected to the first electrical power supply circuit in parallel with the first electrical power storage device, and may be capable of supplying, via the first electrical power supply circuit, the DC electrical power to the first electrical power storage device and the first load device.

### Supplementary Note 4

The electrical power supply system according to Supplementary Note 1 may further include the third electrical power supply circuit (32c) that is connected to the third load device (36c), the fourth electrical power supply circuit (32d) that is connected to the fourth load device (36d), the third electrical power storage device (50c) that is connected via the third disconnection device (58c) to the third electrical power supply circuit, the fourth electrical power storage device (50d) that is connected via the fourth disconnection device (58d) to the fourth electrical power supply circuit, and the second connection circuit (44b) including the second connection device (46b) that is capable of connecting the third electrical power supply circuit and the fourth electrical power supply circuit, wherein the estimation unit may be capable of estimating a second residual capacity, which is a residual capacity of the second electrical power storage device, based on an amount of electrical power that is charged and discharged by the second electrical power storage device, may be capable of estimating a third residual capacity, which is a residual capacity of the third electrical power storage device, based on an amount of electrical power that is charged and discharged by the third electrical power storage device, and may be capable of estimating a fourth residual capacity, which is a residual capacity of the fourth electrical power storage device, based on an amount of electrical power that is charged and discharged by the fourth electrical power storage device, in a state in which, by controlling the first connection device, the first electrical power storage device is connected via the first connection circuit and the first electrical power supply circuit to the second electrical power supply circuit, the update control unit may be capable of disconnecting the second electrical power storage device from the second electrical power supply circuit by controlling the second disconnection device, and may be capable of updating a second residual capacity estimated value, which is the second residual capacity estimated by the estimation unit, based on an open circuit voltage of the second electrical power storage device, in a state in which, by controlling the second connection device, the fourth electrical power storage device is connected via the second connection circuit and the fourth electrical power supply circuit to the third electrical power supply circuit, the update control unit may be capable of disconnecting the third electrical power storage device from the third electrical power supply circuit by controlling the third disconnection device, and may be capable of updating a third residual capacity estimated value, which is the third residual capacity estimated by the estimation unit, based on an open circuit voltage of the third electrical power storage device, in a state in which, by controlling the second connection device, the third electrical power storage device is connected via the second connection circuit and the third electrical power supply circuit to the fourth electrical power supply circuit, the update control unit may be capable of disconnecting the fourth electrical power storage device from the fourth electrical power supply circuit by controlling the fourth disconnection device, and may be capable of updating a fourth residual capacity estimated value, which is the fourth residual capacity estimated by the estimation unit, based on an open circuit voltage of the fourth electrical power storage device, while the first electrical power supply circuit and the second electrical power supply circuit are connected by the first connection device, the update control unit may successively carry out a process of updating the first residual capacity estimated value based on the open circuit voltage of the first electrical power storage device and a process of updating the second residual capacity estimated value based on the open circuit voltage of the second electrical power storage device, and while the third electrical power supply circuit and the fourth electrical power supply circuit are connected by the second connection device, the update control unit may successively carry out a process of updating the third residual capacity estimated value based on the open circuit voltage of the third electrical power storage device and a process of updating the fourth residual capacity estimated value based on the open circuit voltage of the fourth electrical power storage device.

In accordance with the above-described configuration, even if the second load device requires a large amount of electrical power when the second residual capacity estimated value of the second electrical power storage device is being reset, the necessary electrical power can be supplied to the second load device. Further, in accordance with the above-described configuration, even if the third load device requires a large amount of electrical power when the third residual capacity estimated value of the third electrical power storage device is being reset, the necessary electrical power can be supplied to the third load device. Further, in accordance with the above-described configuration, even if the fourth load device requires a large amount of electrical power when the fourth residual capacity estimated value of the fourth electrical power storage device is being reset, the necessary electrical power can be supplied to the fourth load device.

In accordance with the above-described configuration, the number of times that the first connection device is connected and disconnected and the number of times that the second connection device is connected and disconnected can be reduced.

### Supplementary Note 5

The moving object (10) according to the present disclosure is equipped with the electrical power supply system according to any one of Supplementary Notes 1 to 4.

### Supplementary Note 6

The control method of the present disclosure is a control method for controlling the electrical power supply system including the first electrical power supply circuit that is connected to the first load device, the second electrical power supply circuit that is connected to the second load device, the first electrical power storage device that is connected via the first disconnection device to the first electrical power supply circuit, the second electrical power storage device that is connected via the second disconnection device to the second electrical power supply circuit, and the first connection circuit including the first connection device that is capable of connecting the first electrical power supply circuit and the second electrical power supply circuit, the control method including: the first residual capacity estimating step of estimating a first residual capacity, which is a residual capacity of the first electrical power storage device, based on an amount of electrical power that is charged and discharged by the first electrical power storage device; and the first residual capacity estimated value updating step of, in a state in which, by controlling the first connection device, the second electrical power storage device is connected via the first connection circuit and the second electrical power supply circuit to the first electrical power supply circuit, disconnecting the first electrical power storage device from the first electrical power supply circuit by controlling the first disconnection device, and updating a first residual capacity estimated value, which is the first residual capacity estimated in the first residual capacity estimating step, based on an open circuit voltage of the first electrical power storage device.

### Supplementary Note 7

The non-transitory storage medium of the present disclosure stores the program for causing the computer to execute the control method according to Supplementary Note 6.

Although concerning the present disclosure, a detailed description thereof has been presented above, the present disclosure is not necessarily limited to the individual embodiments described above. These embodiments may be subjected to various additions, substitutions, modifications, partial deletions and the like, within a range that does not deviate from the essence and gist of the present disclosure, or the spirit of the present disclosure as derived from the contents described in the claims and equivalents thereof. Further, the embodiments can also be implemented together in combination. For example, in the above-described embodiments, the order of the operations and the order of the processes are illustrated as examples, and the present disclosure is not necessarily limited to these features. The same also applies to cases in which numerical values or mathematical expressions are used in the description of the above-described embodiments.

1. An electrical power supply system, comprising:
a first electrical power supply circuit configured to be connected to a first load device;
a second electrical power supply circuit configured to be connected to a second load device;
a first electrical power storage device configured to be connected via a first disconnection device to the first electrical power supply circuit;
a second electrical power storage device configured to be connected via a second disconnection device to the second electrical power supply circuit;
a first connection circuit including a first connection device configured to connect the first electrical power supply circuit and the second electrical power supply circuit; and
one or more processors that execute a computer-executable instructions stored in a memory,
wherein the one or more processors execute the computer-executable instructions to cause the electrical power supply system to:
estimate a first residual capacity, which is a residual capacity of the first electrical power storage device, based on an amount of electrical power that is charged and discharged by the first electrical power storage device; and
in a state in which, by controlling the first connection device, the second electrical power storage device is connected via the first connection circuit and the second electrical power supply circuit to the first electrical power supply circuit, disconnect the first electrical power storage device from the first electrical power supply circuit by controlling the first disconnection device, and update a first residual capacity estimated value, which is the first residual capacity that has been estimated, based on an open circuit voltage of the first electrical power storage device.

2. The electrical power supply system according to claim 1, further comprising a first electrical power source configured to be connected to the first electrical power supply circuit and configured to charge the first electrical power storage device.

3. The electrical power supply system according to claim 2, wherein
the first electrical power source is connected to the first electrical power supply circuit in parallel with the first electrical power storage device, and is configured to supply, via the first electrical power supply circuit, a direct current electrical power to the first electrical power storage device and the first load device.

4. The electrical power supply system according to claim 1, further comprising:
a third electrical power supply circuit configured to be connected to a third load device;
a fourth electrical power supply circuit configured to be connected to a fourth load device;
a third electrical power storage device configured to be connected via a third disconnection device to the third electrical power supply circuit;
a fourth electrical power storage device configured to be connected via a fourth disconnection device to the fourth electrical power supply circuit; and
a second connection circuit including a second connection device configured to connect the third electrical power supply circuit and the fourth electrical power supply circuit,
wherein the one or more processors cause the electrical power supply system to:
estimate a second residual capacity, which is a residual capacity of the second electrical power storage device, based on an amount of electrical power that is charged and discharged by the second electrical power storage device;
estimate a third residual capacity, which is a residual capacity of the third electrical power storage device, based on an amount of electrical power that is charged and discharged by the third electrical power storage device;
estimate a fourth residual capacity, which is a residual capacity of the fourth electrical power storage device, based on an amount of electrical power that is charged and discharged by the fourth electrical power storage device;
in a state in which, by controlling the first connection device, the first electrical power storage device is connected via the first connection circuit and the first electrical power supply circuit to the second electrical power supply circuit, disconnect the second electrical power storage device from the second electrical power supply circuit by controlling the second disconnection device, and update a second residual capacity estimated value, which is the second residual capacity that has been estimated, based on an open circuit voltage of the second electrical power storage device;
in a state in which, by controlling the second connection device, the fourth electrical power storage device is connected via the second connection circuit and the fourth electrical power supply circuit to the third electrical power supply circuit, disconnect the third electrical power storage device from the third electrical power supply circuit by controlling the third disconnection device, and update a third residual capacity estimated value, which is the third residual capacity that has been estimated, based on an open circuit voltage of the third electrical power storage device;
in a state in which, by controlling the second connection device, the third electrical power storage device is connected via the second connection circuit and the third electrical power supply circuit to the fourth electrical power supply circuit, disconnect the fourth electrical power storage device from the fourth electrical power supply circuit by controlling the fourth disconnection device, and update a fourth residual capacity estimated value, which is the fourth residual capacity that has been estimated, based on an open circuit voltage of the fourth electrical power storage device;
while the first electrical power supply circuit and the second electrical power supply circuit are connected by the first connection device, successively carry out a process of updating the first residual capacity estimated value based on the open circuit voltage of the first electrical power storage device and a process of updating the second residual capacity estimated value based on the open circuit voltage of the second electrical power storage device; and
while the third electrical power supply circuit and the fourth electrical power supply circuit are connected by the second connection device, successively carry out a process of updating the third residual capacity estimated value based on the open circuit voltage of the third electrical power storage device and a process of updating the fourth residual capacity estimated value based on the open circuit voltage of the fourth electrical power storage device.

5. A moving object comprising the electrical power supply system according to claim 1.

6. A control method for controlling, by one or more processors, an electrical power supply system including a first electrical power supply circuit configured to be connected to a first load device, a second electrical power supply circuit configured to be connected to a second load device, a first electrical power storage device configured to be connected via a first disconnection device to the first electrical power supply circuit, a second electrical power storage device configured to be connected via a second disconnection device to the second electrical power supply circuit, and a first connection circuit including a first connection device configured to connect the first electrical power supply circuit and the second electrical power supply circuit, the control method comprising:
estimating a first residual capacity, which is a residual capacity of the first electrical power storage device, based on an amount of electrical power that is charged and discharged by the first electrical power storage device; and
in a state in which, by controlling the first connection device, the second electrical power storage device is connected via the first connection circuit and the second electrical power supply circuit to the first electrical power supply circuit, disconnecting the first electrical power storage device from the first electrical power supply circuit by controlling the first disconnection device, and updating a first residual capacity estimated value, which is the first residual capacity that has been estimated, based on an open circuit voltage of the first electrical power storage device.

7. A non-transitory storage medium storing a program for causing a computer to execute the control method according to claim 6.
